(19) United States
(12) Patent Application Publication
(10) Pub. No.: US 2026/0168081 A1
(43) Pub. Date: Jun. 18, 2026

(54) SUBSTRATE PROCESSING METHOD AND SUBSTRATE PROCESSING APPARATUS

(71) Applicant: Tokyo Electron Limited, Tokyo (JP)

(72) Inventors: Tenta USHIDA, Nirasaki City (JP); Tadashi MITSUNARI, Nirasaki City (JP); Miyako KANEKO, Nirasaki City (JP)

(21) Appl. No.: 19/419,642

(22) Filed: Dec. 15, 2025

(30) Foreign Application Priority Data
Dec. 17, 2024 (JP) 2024-221114

(51) Int. Cl. C23C 16/04; C23C 16/32; C23C 16/458; C23C 16/505; C23C 16/52

(52) U.S. Cl. CPC C23C 16/04; C23C 16/32; C23C 16/4583; C23C 16/505; C23C 16/52

(57) ABSTRACT

A substrate processing method includes: preparing a substrate having an uneven pattern of a protrusion and a recess; and selectively forming a film containing tungsten and carbon on a top portion of the protrusion of the substrate by generating plasma of a process gas including a film-forming gas, which includes a WF₆ gas and a CO gas, and an inert gas.

### CROSS-REFERENCE TO RELATED APPLICATION

This application is based upon and claims the benefit of priority from Japanese Patent Application No. 2024-221114, filed on Dec. 17, 2024, the entire content of which is incorporated herein by reference.

### TECHNICAL FIELD

The present disclosure relates to a substrate processing method and a substrate processing apparatus.

### BACKGROUND

Patent Document 1 discloses an etching method for forming tungsten-containing deposits that are etch-resistant.

### PRIOR ART DOCUMENT

### Patent Document

Patent Document 1: Japanese Laid-open Patent Application Publication No. 2023-008824

### SUMMARY

According to one embodiment of the present disclosure, there is provided a substrate processing method including: preparing a substrate having an uneven pattern of a protrusion and a recess; and selectively forming a film containing tungsten and carbon on a top portion of the protrusion of the substrate by generating plasma of a process gas including a film-forming gas, which includes a WF₆ gas and a CO gas, and an inert gas.

### BRIEF DESCRIPTION OF DRAWINGS

The accompanying drawings, which are incorporated in and constitute a part of this specification, illustrate embodiments of the present disclosure, and together with the general description given above and the detailed description of the embodiments given below, serve to explain the principles of the present disclosure.

FIG. 1 is a schematic cross-sectional view showing an example of a substrate processing apparatus according to an embodiment.

FIG. 2 is an example of a flowchart illustrating a substrate processing method.

FIG. 3 is an example of a schematic cross-sectional view of a prepared substrate.

FIG. 4 is an example of a schematic cross-sectional view of a substrate after a tungsten- and carbon-containing film has been formed.

FIG. 5 is an example of a cross-sectional view showing the shape of a tungsten- and carbon-containing film.

FIG. 6 is an example of a cross-sectional view showing the shape of a tungsten- and carbon-containing film.

FIG. 7 is an example of a cross-sectional view showing the shape of a tungsten-containing film of a reference example.

FIG. 8 is an example of a cross-sectional view showing the shape of a tungsten- and carbon-containing film.

FIG. 9 is an example of a cross-sectional view showing the shape of a tungsten- and carbon-containing film.

FIG. 10 is an example of a cross-sectional view showing the shape of a tungsten- and carbon-containing film.

FIG. 11 is an example of a cross-sectional view showing the shape of a tungsten- and carbon-containing film.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of the present disclosure will be described below with reference to the drawings. Throughout the drawings, the same components are denoted by the same reference numerals, and duplicated explanations thereof may be omitted.

### [Substrate Processing Apparatus 1]

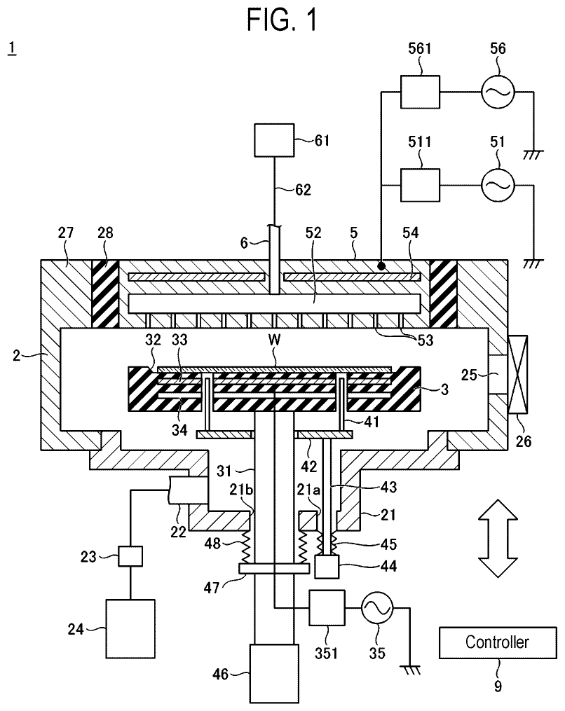

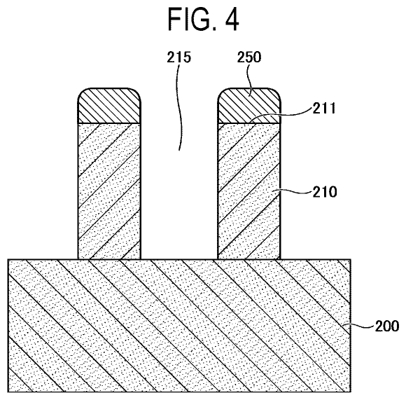

A substrate processing apparatus 1 according to an embodiment will be described with reference to FIG. 1. FIG. 1 is a schematic cross-sectional view showing an example of the substrate processing apparatus 1 according to this embodiment. The substrate processing apparatus 1 is an apparatus that selectively forms a film containing tungsten (W) and carbon (C) (hereinafter, tungsten- and carbon-containing film) on a substrate W, such as a wafer, by using a plasma-enhanced chemical vapor deposition (PECVD) method inside a depressurized process container 2. The tungsten- and carbon-containing film is selectively formed on a top portion 211 of a protrusion formed on the substrate W (see FIGS. 3 and 4 to be described later).

The substrate processing apparatus 1 includes a substantially cylindrical and airtight process container 2. An exhaust chamber 21 is provided in a center portion of a bottom wall of the process container 2.

The exhaust chamber 21 is formed in, for example, a substantially cylindrical shape that protrudes downward. An exhaust flow path 22 is connected to the exhaust chamber 21, for example, at a side surface of the exhaust chamber 21. An exhauster 24 is connected to the exhaust flow path 22 via a pressure adjuster 23. The pressure adjuster 23 includes a pressure adjustment valve such as a butterfly valve. The exhaust flow path 22 is configured to depressurize an internal pressure of the process container 2 by using the exhauster 24. A transfer port 25 is provided at a side surface of the process container 2. The transfer port 25 is configured to be opened and closed by a gate valve 26. Substrates W are loaded and unloaded between the process container 2 and a transfer chamber (not shown) through the transfer port 25.

A stage (substrate support) 3 for holding the substrate W in a substantially horizontal posture is provided inside the process container 2. The stage 3 is substantially circular in a plan view and is supported by a support member 31. A substantially circular concave portion 32 for placing a substrate W having a diameter of, e.g., 300 mm is formed in a surface of the stage 3. The concave portion 32 has an inner diameter that is slightly larger (e.g., approximately 1 mm to 4 mm) than the diameter of the substrate W. A depth of the concave portion 32 is configured to be approximately the same as a thickness of the substrate W. The stage 3 is made of a ceramic material such as aluminum nitride (AlN). The stage 3 may also be made of a metal material such as nickel (Ni). Instead of the concave portion 32, a guide ring for guiding the substrate W may be provided around a periphery of the surface of the stage 3.

A lower electrode 33 is embedded in the stage 3. A temperature adjuster 34 is embedded below the lower electrode 33. The temperature adjuster 34 adjusts a temperature of the substrate W placed on the stage 3 to a set temperature based on a control signal from a controller 9. In a case where an entire stage 3 is made of metal, the stage 3 itself functions as the lower electrode and therefore, the lower electrode 33 may not be embedded in the stage 3.

An RF power source 35 is connected to the lower electrode 33 via a matcher 351. The RF power source 35 applies low radio-frequency power (LF: Low Frequency), which has a frequency lower than that of an RF power source 51 to be described later, to the lower electrode 33. The radio-frequency power generated by the RF power source 35 is used as bias radio-frequency power for attracting ions into the substrate W. The frequency of the RF power source 35 is, for example, 13.56 MHz. The lower electrode 33 may be connected to a bias DC power source and supplied with bias DC power or pulsed DC power, or may be grounded.

The stage 3 is provided with a plurality of (e.g., three) lift pins 41 for holding and lifting the substrate W placed on the stage 3. The lift pins 41 may be made of a ceramic material, such as alumina (Al₂O₃), quartz, or the like. Lower ends of the lift pins 41 are attached to a support plate 42. The support plate 42 is connected to a lifter 44, which is provided outside the process container 2, via a lift shaft 43.

The lifter 44 is provided, for example, below the exhaust chamber 21. A bellows 45 is provided between the lifter 44 and an opening 21a for the lift shaft 43, formed in a lower surface of the exhaust chamber 21. The support plate 42 may be shaped so that the support plate 42 can be raised and lowered without interfering with the support member 31 of the stage 3. The lift pins 41 are configured to be raised and lowered between an upper side and a lower side of the surface of the stage 3 by the lifter 44. In other words, the lift pins 41 are configured to be able to protrude from an upper surface of the stage 3.

In addition, a lower end portion of the support member 31 penetrates an opening 21b of the exhaust chamber 21 and is supported by a lifter 46 via a lift plate 47 disposed below the process container 2. A bellows 48 is provided between a bottom of the exhaust chamber 21 and the lift plate 47 and maintains airtightness inside the process container 2 even when the lift plate 47 moves up and down.

The lifter 46 raises and lowers the lift plate 47, which raises and lowers the stage 3. Therefore, a gap between the stage 3 and a gas supply 5 can be adjusted.

The gas supply 5 is attached to a ceiling wall 27 of the process container 2 via an insulating member 28. The gas supply 5 serves as an upper electrode and faces the lower electrode 33. RF power sources 51 and 56 (plasma generator) are connected to the gas supply 5 via matchers 511 and 561, respectively. The RF power source 51 applies radio-frequency power to the upper electrode (the gas supply 5). The radio-frequency power generated by the RF power source 51 is used as radio-frequency power for plasma generation that is required to form a film on the substrate W. A frequency of the RF power source 51 is, for example, 13 MHz to 220 MHz (e.g., 13 MHz). The RF power source 56 also applies radio-frequency power to the upper electrode (the gas supply 5). The radio-frequency power generated by the RF power source 56 is used as radio-frequency power for plasma generation that is required to form a film on the substrate W. A frequency of the RF power source 56 is a frequency (e.g., 450 kHz) lower than the frequency of the RF power source 51. By supplying at least one of RF power from the RF power source 51 or RF power from the RF power source 56 to the upper electrode (the gas supply 5), an RF electric field is generated between the upper electrode (the gas supply 5) and the lower electrode 33. The number of RF power sources may be two (dual frequency) or one (single frequency). The gas supply 5 includes a hollow gas diffusion chamber 52. Multiple holes 53 for dispersing and supplying a process gas into the process container 2 are disposed, for example, evenly, on a lower surface of the gas diffusion chamber 52. A heater 54 is embedded in the gas supply 5, for example, above the gas diffusion chamber 52. The heater 54 is heated to a set temperature by receiving power from a power source (not shown) based on a control signal from the controller 9.

A gas supply path 6 is provided in the gas diffusion chamber 52. The gas supply path 6 is in communication with the gas diffusion chamber 52. A gas source (gas supply source) 61 is connected to an upstream side of the gas supply path 6 via a gas line 62. The gas source 61 includes, for example, various process gas supply sources, mass flow controllers, and valves (none of which are shown). Various process gases are introduced from the gas source 61 into the gas diffusion chamber 52 via the gas line 62. The various process gases are then supplied from the gas diffusion chamber 52 into a process space of the process container 2 via the holes 53.

The various process gases include a film-forming gas. The film-forming gas includes a gas containing tungsten (W) and a gas containing carbon (C). Specifically, the film-forming gas includes a tungsten hexafluoride (WF₆) gas and a carbon monoxide (CO) gas.

The film-forming gas may also include a gas containing hydrogen (H). Specifically, the film-forming gas may include a hydrogen (H₂) gas.

The various process gases may also include an inert gas. Specifically, the inert gas includes any of an argon (Ar) gas, a helium (He) gas, a neon (Ne) gas, and the like.

The various process gases may also include a carrier gas (e.g., at least one selected from the group consisting of Ar, He, N₂, H₂, and the like.).

The substrate processing apparatus 1 includes the controller 9. The controller 9 is, for example, a computer and includes a central processing unit (CPU), and a computer-readable storage medium, such as, a random access memory (RAM), a read-only memory (ROM), and an auxiliary memory. The CPU operates based on a program stored in the ROM or the auxiliary memory to control the operation of the substrate processing apparatus 1. The controller 9 may be provided inside or outside the substrate processing apparatus 1. In a case where the controller 9 is provided outside the substrate processing apparatus 1, the controller 9 can control the substrate processing apparatus 1 via wired or wireless communication means.

### [Substrate Processing Method]

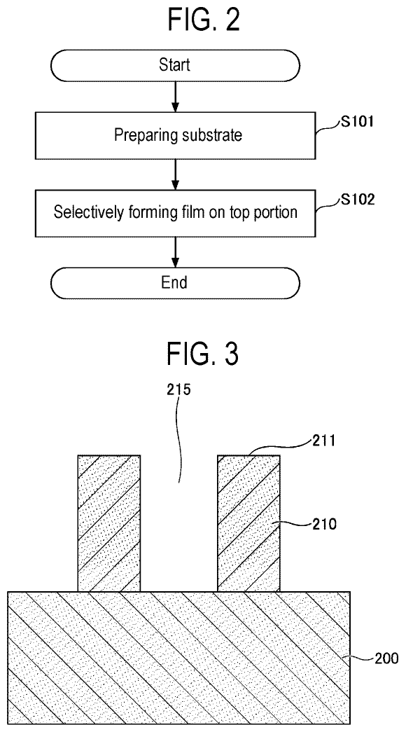

Next, an example of a substrate processing method will be described with reference to FIGS. 2 to 4. FIG. 2 is an example of a flowchart illustrating the substrate processing method.

In step S101, a substrate W is prepared. Here, the controller 9 controls a substrate transporter (not shown) to place the substrate W on the stage 3 in the process container 2. The controller 9 also controls the pressure adjuster 23 to adjust the internal pressure of the process container 2 to a predetermined pressure. The controller 9 also controls the temperature adjuster 34 to adjust a temperature of the stage 3 (in other words, the temperature of the substrate W placed on the stage 3) at a predetermined temperature.

FIG. 3 is an example of a schematic cross-sectional view of the prepared substrate W.

The substrate W has an uneven pattern. In other words, the substrate W has recesses such as holes and trenches. In the example shown in FIG. 3, the substrate W has a base film 200 and an upper film 210 which is formed on the base film 200. The base film 200 is, for example, a silicon oxide (SiO₂) film. The upper film 210 is, for example, an amorphous silicon (a-Si) film. Materials of the base film 200 and the upper film 210 are not limited to these materials.

Further, the upper film 210 has a pattern of openings 215. In other words, the substrate W has an uneven pattern of recesses formed by the openings 215 of the upper film 210 and protrusions formed by the top portions 211 of the upper film 210. For example, the base film 200 may be an etching target film, and the upper film 210 having the pattern of openings 215 may be a film used as a mask when etching the base film 200.

In addition, the base film 200 may be a single-layer film or a stacked film (e.g., a stacked film formed by alternately stacking a silicon oxide layer and a silicon nitride layer). The upper film 210 may also be a single-layer film or a stacked film (e.g., a stacked film including a carbon film (e.g., SOC: Spin On Carbon) and a silicon-containing film (e.g., SOG: Spin On Glass) formed on the carbon film).

In addition, the substrate W may have any shape of uneven patterns, and is not limited to a configuration in which the pattern of openings 215 is formed such that the openings 215 penetrate to a lower surface of the upper film 210 and the base film 200 is exposed from the bottoms of the openings 215, as shown in the example of the schematic cross-sectional view of the substrate W in FIG. 3. For example, the substrate W may have a configuration in which recesses that do not penetrate to the lower surface of the upper film 210 are formed on an upper surface side of the upper film 210.

In step S102, a tungsten- and carbon-containing film 250 is selectively formed on the top portion 211 of the substrate W. Here, plasma of a process gas including a film-forming gas, which includes a tungsten (W)-containing gas (specifically, WF₆) and a carbon (C)-containing gas (specifically, CO), and an inert gas (e.g., Ar) is generated. A precursor (WF₆) of the tungsten (W)-containing gas is reduced with the carbon (C)-containing gas (CO) by a PECVD method, and the tungsten- and carbon-containing film 250 is selectively formed on the top portion 211 of the substrate W. Further, by reducing the precursor (WF₆) of the tungsten (W)-containing gas with the carbon (C)-containing gas (CO), removal of fluorine (F) from the film 250 is promoted, and a film quality of the film 250 is improved.

The controller 9 controls the gas source 61 to supply the process gas (the film-forming gas and the inert gas) from the gas supply 5 into the process container 2 and controls at least one of the RF power source 51 or the RF power source 56 to supply the RF power for plasma generation to the upper electrode. Thus, plasma of the process gas is generated in the process container 2. Subsequently, the substrate W placed on the stage 3 is exposed to the plasma of the process gas, and therefore, the tungsten- and carbon-containing film 250 is selectively formed on the top portion 211 of the substrate W.

FIG. 4 is an example of a schematic cross-sectional view of the substrate W after the tungsten- and carbon-containing film 250 has been formed.

As shown in FIG. 4, the tungsten- and carbon-containing film 250 is selectively formed on the top portion 211 of the upper film 210.

Further, a hydrogen (H)-containing gas (specifically, H₂) may be added to the film-forming gas. The precursor (WF₆) of the tungsten (W)-containing gas is reduced by the carbon (C)-containing gas (CO) and the hydrogen (H)-containing gas (H₂).

Here, a carbon composition ratio in the tungsten- and carbon-containing film 250 is controlled by controlling a flow rate ratio of the CO gas to the H₂ gas. Specifically, the larger the flow rate ratio of the CO gas to the H₂ gas, the greater the carbon composition ratio in the tungsten- and carbon-containing film 250.

Further, a shape of the tungsten- and carbon-containing film 250 is controlled by controlling the flow rate ratio of the CO gas to the H₂ gas. Specifically, the larger the flow rate ratio of the CO gas to the H₂ gas, the more selectively the tungsten- and carbon-containing film 250 is formed on the top portion 211.

After the film-formation process of the tungsten- and carbon-containing film 250, the controller 9 controls the substrate transporter (not shown) to unload the substrate W from the process container 2. This completes the substrate processing shown in FIG. 2.

When etching the base film 200 using the upper film 210 having the openings 215 as a mask, the tungsten- and carbon-containing film 250 can be used as a protective film to protect the top portion 211 of the upper film 210. Consequently, wear of the upper film 210 during etching can be suppressed. In other words, compared to a case in which the tungsten- and carbon-containing film 250 is not formed, forming the tungsten- and carbon-containing film 250 allows a thickness of the upper film 210 to be made thinner. This reduces an aspect ratio of the recess, which improves the etching profile formed in the base film 200.

Further, the tungsten- and carbon-containing film 250, which is a metal-containing carbon film with high etching resistance, can be formed as a protective film to protect the top portion 211 of the upper film 210.

### [Shape of Film 250]

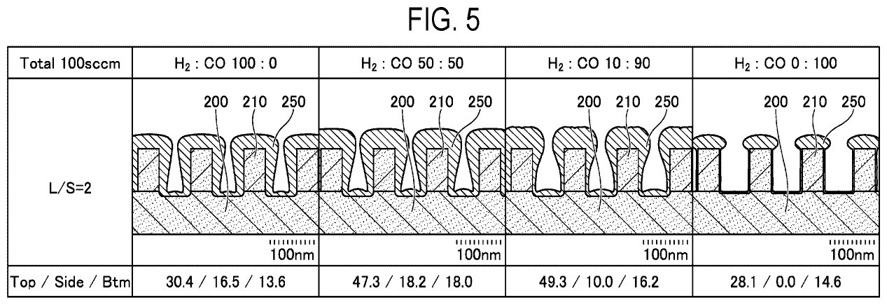

Next, a relationship between the flow rate ratio of CO gas to H₂ gas in the process gas (the film-forming gas) and the shape of the tungsten- and carbon-containing film 250 will be described with reference to FIG. 5. FIG. 5 is an example of a cross-sectional view showing the shape of the tungsten- and carbon-containing film 250. Here, the base film 200 made of SiO₂ and the upper film 210 made of amorphous silicon were formed on the substrate W, and the uneven pattern with a Line CD (critical dimension) to Space CD ratio (L/S) of 2 was formed in the upper film 210. The film 250 was formed, on the substrate W having the uneven pattern, with the flow rate ratios of H₂:CO set to 100:0, 50:50, 10:90, and 0:100.

In the example shown in FIG. 5, process conditions were set as the following:
WF₆ flow rate: 5 sccm
Total flow rate of H₂ and CO: 100 sccm
Ar (inert gas) flow rate: 10 sccm
Frequency and power of radio-frequency power for plasma generation: 450 kHz, 50 W
Internal pressure of process container 2: 0.5 Torr
Temperature of substrate W: 100 degrees C.

Further, a film thickness (TOP) of the film 250 formed on an upper surface (the top portion 211) of the protrusion, a film thickness (Side) of the film 250 on a sidewall of the recess (the opening 215), and a film thickness (Btm) of the film 250 on a bottom surface of the recess (the opening 215) were measured. The unit of TOP/Side/Btm in FIG. 5 is [nm].

As shown in FIG. 5, the shape of the film 250 can be controlled by controlling the flow rate ratio of H₂ and CO.

Specifically, when the flow rate ratio of H₂:CO is “100:0,” the WF₆ precursor is reduced by H₂, which decreases a fluorine (F) content in the film and allows the formation of the film 250 with high film quality. Meanwhile, as shown in FIG. 5, the film 250 is conformally formed not only on the upper surface of the protrusion, but also on the sidewall and bottom surface of the recess.

In contrast, as the flow rate ratio of H₂:CO decreases, a greater amount of film is formed on the top portion 211 of the protrusion. Specifically, compared to when the H₂:CO flow rate ratio is 100:0, when the H₂:CO flow rate ratio is 50:50 or 10:90, the film thickness of the film 250 formed on the top portion 211 of the protrusion can be made thicker. As such, by setting the flow rate ratio (CO/H₂) of CO gas to H₂ gas to 1 or greater, the film thickness of the film 250 formed on the top portion 211 of the protrusion can be made thicker. Further, the film thickness of the film 250 formed on the top portion 211 of the protrusion can be made thicker than the film thickness of the film 250 formed on the bottom surface of the recess.

Further, carbon (C) ions are attracted toward the substrate W by the bias radio-frequency power. In the film 250 formed on the top portion 211 of the protrusion, carbon (C) ions collide with the film 250 and cause dissociation of fluorine (F) in the film 250, which improves the film quality. On the other hand, in the film 250 formed on the sidewall and bottom surface of the recess, the modifying effect of carbon (C) ions is decreased. Therefore, the film quality of the film 250 formed on the sidewall and bottom surface of the recess is lower than that of the film 250 formed on the top portion 211 of the protrusion.

After the film 250 is formed, by performing an etching process (e.g., a plasma etching process using a CF₄ gas and an Ar gas), the film 250 formed on the sidewall and bottom surface of the recess is etched away faster than the film 250 formed on the top portion 211 of the protrusion, while the film 250 formed on the top portion 211 of the protrusion remains. This allows the film 250 to be selectively formed on the top portion 211 of the protrusion. In other words, the film 250 can be formed vertically from the top portion 211 of the protrusion. The process of etching the film 250 formed on the sidewall and bottom surface of the recess and the process of etching the base film 200 by using the upper film 210 as a mask may be separate processes or the same process.

When the WF₆ gas and the CO gas are used as the film-forming gas without H₂ gas (H₂:CO flow rate ratio is 0:100), the formation of the film 250 on the sidewall of the recess can be suppressed. That is, the film 250 can be formed vertically from the top portion 211 of the protrusion. Further, the film 250 formed on the top portion 211 of the protrusion can be made thicker than the film 250 formed on the bottom surface of the recess. Further, by reducing the WF₆ precursor with CO, the fluorine (F) content in the film can be decreased, allowing the formation of the film 250 with high film quality.

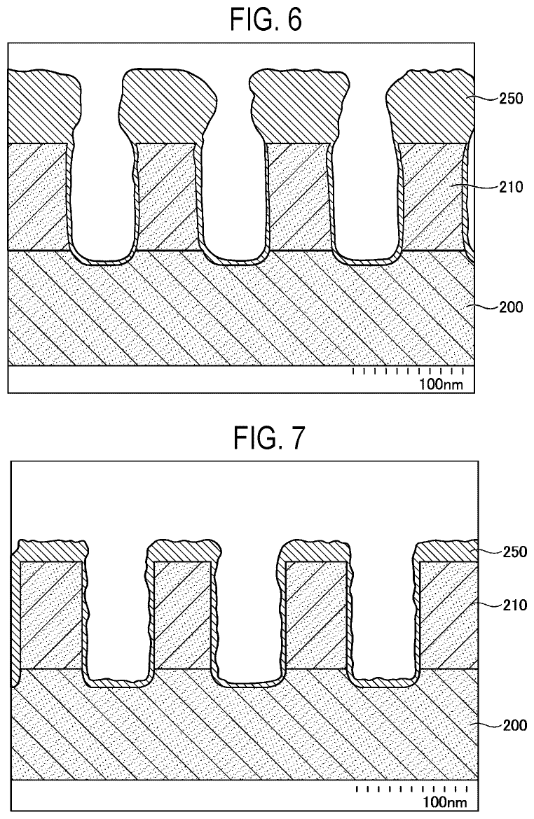

FIG. 6 is an example of a cross-sectional view showing the shape of the tungsten- and carbon-containing film 250. Here, the WF₆ gas and the CO gas were used as the film-forming gas.

That is, in the example shown in FIG. 6, the process conditions were set as the following:
WF₆ flow rate: 5 sccm
CO flow rate: 100 sccm
Ar (inert gas) flow rate: 10 sccm
Frequency and power of radio-frequency power for plasma generation: 13 MHz, 50 W
Internal pressure of process container 2: 0.5 Torr
Temperature of substrate W: 100 degrees C.

FIG. 7 is an example of a cross-sectional view showing the shape of a tungsten-containing film 250 of a reference example. Here, only the WF₆ gas was used as the film-forming gas.

That is, in the example shown in FIG. 7, the process conditions were set as the following:
WF₆ flow rate: 5 sccm
Ar (inert gas) flow rate: 10 sccm
Frequency and power of radio-frequency power for plasma generation: 13 MHz, 50 W
Internal pressure of process container 2: 0.5 Torr
Temperature of substrate W: 100 degrees C.

As shown by comparing FIGS. 6 and 7, when the WF₆ gas and the CO gas are used (see FIG. 6), the film 250 formed on the top portion 211 of the protrusion can be made thicker than when only the WF₆ gas is used (see FIG. 7). Further, since a reducing agent (H₂, CO) was not used in the tungsten-containing film 250 of the reference example (see FIG. 7), the film contains a lot of fluorine (F) and has poor film quality. In contrast, in the tungsten- and carbon-containing film 250 (see FIG. 6), the fluorine (F) content in the film is decreased and the film quality is improved.

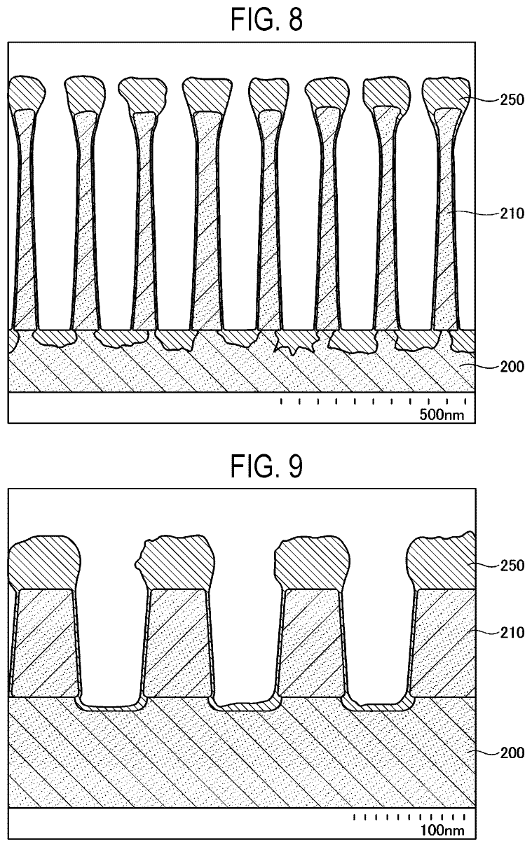

FIG. 8 is an example of a cross-sectional view showing the shape of the tungsten- and carbon-containing film 250. Here, the temperature of the substrate W was set to be higher than that in FIG. 6.

That is, in the example shown in FIG. 8, the process conditions were set as the following:
WF₆ flow rate: 5 sccm
CO flow rate: 100 sccm
Ar (inert gas) flow rate: 10 sccm
Frequency and power of radio-frequency power for plasma generation: 13 MHz, 50 W
Internal pressure of process container 2: 0.5 Torr
Temperature of substrate W: 300 degrees C.

As shown in FIGS. 6 and 8, the film thickness of the film 250 formed on the top portion 211 of the protrusion can be made thicker when the temperature of the substrate W during film formation is within a temperature range of 300 degrees C. or lower. That is, the film 250 can be formed vertically from the top portion 211 of the protrusion. Further, the film thickness of the film 250 formed on the top portion 211 of the protrusion can be increased when the temperature of the substrate W during film formation is within a temperature range of 100 degrees C. to 300 degrees C.

FIG. 9 is an example of a cross-sectional view showing the shape of the tungsten- and carbon-containing film 250. Here, the internal pressure of the process container 2 was set to be higher than that in FIG. 8.

That is, in the example shown in FIG. 9, the process conditions were set as the following:
WF₆ flow rate: 5 sccm
CO flow rate: 100 sccm
Ar (inert gas) flow rate: 10 sccm
Frequency and power of radio-frequency power for plasma generation: 13 MHz, 50 W
Internal pressure of process container 2: 2 Torr
Temperature of substrate W: 200 degrees C.

FIG. 10 is an example of a cross-sectional view showing the shape of the tungsten- and carbon-containing film 250. Here, the internal pressure of the process container 2 was set to be higher than that in FIG. 8, and the temperature of the substrate W was set to be higher than that in FIG. 9.

That is, in the example shown in FIG. 10, the process conditions were set as the following:
WF₆ flow rate: 5 sccm
CO flow rate: 100 sccm
Ar (inert gas) flow rate: 10 sccm
Frequency and power of radio-frequency power for plasma generation: 13 MHz, 50 W
Internal pressure of process container 2: 2 Torr
Temperature of substrate W: 300 degrees C.

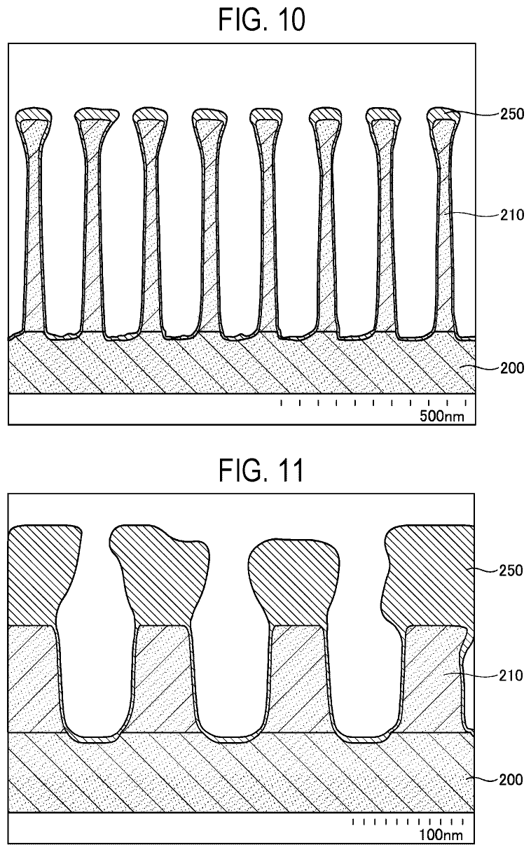

FIG. 11 is an example of a cross-sectional view showing the shape of the tungsten- and carbon-containing film 250. Here, the internal pressure of the process container 2 was set to be higher than that in FIG. 6.

That is, in the example shown in FIG. 11, the process conditions were set as the following:
WF₆ flow rate: 5 sccm
CO flow rate: 100 sccm
Ar (inert gas) flow rate: 10 sccm
Frequency and power of radio-frequency power for plasma generation: 13 MHz, 50 W
Internal pressure of process container 2: 4 Torr
Temperature of substrate W: 100 degrees C.

As shown in FIGS. 6 and 11, the film thickness of the film 250 formed on the top portion 211 of the protrusion can be increased when the internal pressure of the process container 2 during film formation is within a range of 0.5 Torr to 5 Torr. That is, the film 250 can be formed vertically from the top portion 211 of the protrusion.

The substrate processing method for forming a tungsten- and carbon-containing film has been described above. However, the present disclosure is not limited to the above embodiments, and various modifications and improvements can be made within the scope of the gist of the present disclosure as set forth in the claims.

According to the present disclosure in some embodiments, it is possible to provide a substrate processing method and a substrate processing apparatus for selectively forming a tungsten- and carbon-containing film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method comprising:
preparing a substrate having an uneven pattern of a protrusion and a recess; and
selectively forming a film containing tungsten and carbon on a top portion of the protrusion of the substrate by generating plasma of a process gas including a film-forming gas, which includes a WF₆ gas and a CO gas, and an inert gas.

2. The substrate processing method of claim 1, wherein the film-forming gas further includes a H₂ gas.

3. The substrate processing method of claim 1, wherein the inert gas includes at least one of an Ar gas, a He gas, or a Ne gas.

4. The substrate processing method of claim 2, wherein a carbon composition ratio in the film containing tungsten and carbon increases as a flow rate ratio of the CO gas to the H₂ gas increases.

5. The substrate processing method of claim 2, wherein the film containing tungsten and carbon is more selectively formed on the top portion as a flow rate ratio of the CO gas to the H₂ gas increases.

6. The substrate processing method of claim 2, wherein a flow rate ratio of the CO gas to the H₂ gas is 1 or greater.

7. The substrate processing method of claim 6, further comprising:
after the forming the film containing tungsten and carbon, etching the substrate,
wherein the etching the substrate leaves the film containing tungsten and carbon formed on the top portion.

8. The substrate processing method of claim 1, wherein, in the forming the film containing tungsten and carbon, a temperature of the substrate is within a temperature range of 300 degrees C. or lower.

9. The substrate processing method of claim 1, wherein, in the forming the film containing tungsten and carbon, a pressure within a process container, in which the substrate is accommodated, is within a pressure range of 0.5 Torr to 5 Torr.

10. A substrate processing apparatus for forming a film containing tungsten and carbon, comprising:
a substrate support configured to support a substrate;
a process container configured to accommodate the substrate support;
a gas supply configured to supply a process gas into the process container;
a plasma generator configured to generate plasma of the process gas; and
a controller,
wherein the controller performs:
placing the substrate having an uneven pattern of a protrusion and a recess on the substrate support; and
selectively forming the film containing tungsten and carbon on a top portion of the protrusion of the substrate by generating plasma of the process gas including a film-forming gas, which includes a WF₆ gas and a CO gas, and an inert gas.
